(19) United States
(12) Patent Application Publication
(10) Pub. No.: US 2025/0267853 A1
(43) Pub. Date: Aug. 21, 2025

(54) MEMORY INCLUDING BIT LINE PILLAR

(71) Applicant: SK hynix Inc., Gyeonggi-do (KR)

(72) Inventors: Dong Kyu KIM, Gyeonggi-do (KR); Youn Guk KIM, Gyeonggi-do (KR); Ho Seok EM, Gyeonggi-do (KR); Hyung Sik WON, Gyeonggi-do (KR); Jeong Jun LEE, Gyeonggi-do (KR); Jun Ho CHEON, Gyeonggi-do (KR)

(21) Appl. No.: 18/625,666

(22) Filed: Apr. 3, 2024

(30) Foreign Application Priority Data
Feb. 15, 2024 (KR) 10-2024-0021609

(51) Int. Cl. H10B 12/00

(52) U.S. Cl. CPC H10B 12/482; H10B 12/50

(57) ABSTRACT

A memory may include a plurality of word lines formed of N layers, M word lines being arranged in each layer, among the plurality of word lines, where each of N and M is an integer of 2 or more; a plurality of bit line pillars; and a plurality of memory cells disposed at intersections between the plurality of word lines and the plurality of bit line pillars, respectively. Among the plurality of word lines, two or more word lines of the plurality of word lines may be grouped and driven together.

### CROSS-REFERENCE TO RELATED APPLICATION

This application claims priority under 35 U.S.C. § 119(a) to Korean Patent Application No. 10-2024-0021609 filed on Feb. 15, 2024, which is incorporated herein by reference in its entirety.

### BACKGROUND

### 1. Technical Field

Embodiments of the present disclosure relate to a memory, and more particularly, to a memory including a three-dimensional memory cell.

### 2. Related Art

Recently, in order to cope with an increase in capacity and miniaturization of a memory, a technology for implementing a three-dimensional (3D) memory in which a plurality of memory cells are stacked has been studied.

### SUMMARY

In an embodiment of the present disclosure, a memory may include a plurality of word lines formed of N layers, M word lines being arranged in each layer, among the plurality of word lines, where each of N and M is an integer of 2 or more; a plurality of bit line pillars; and a plurality of memory cells disposed at intersections between the plurality of word lines and the plurality of bit line pillars, respectively, wherein two or more word lines of the plurality of word lines may be grouped and driven together.

In an embodiment of the present disclosure, a memory may include a plurality of word lines; a plurality of bit lines; and a plurality of memory cells connected to one of the plurality of word lines and one of the plurality of bit lines, wherein two or more word lines of the plurality of word lines may be grouped and driven together.

### BRIEF DESCRIPTION OF THE DRAWINGS

FIGS. 1 and 2 are diagrams illustrating the structure of word lines in a cell array of a memory in accordance with an embodiment of the present disclosure.

FIG. 3 is a diagram illustrating bit lines for electrical connection among bit line pillars in FIGS. 1 and 2.

FIG. 4 is a side view of the cell array illustrated in FIGS. 1 to 3.

FIG. 5 is a circuit diagram illustrating electrical connection among word lines, the bit line pillars, and memory cells of an Nth layer in the cell array illustrated in FIGS. 1 to 4.

FIG. 6 is a diagram illustrating the structure of word lines in a cell array of a memory in accordance with another embodiment of the present disclosure.

FIG. 7 is a diagram illustrating bit lines for electrical connection among bit line pillars in FIG. 6.

FIG. 8 is a side view of the cell array illustrated in FIGS. 6 and 7.

FIG. 9 is a circuit diagram illustrating electrical connection among word lines, the bit line pillars, and memory cells of an Nth layer in the cell array illustrated in FIGS. 6 to 8.

### DETAILED DESCRIPTION

Various embodiments of the present disclosure are directed to providing a more highly integrated memory with a reduced area.

Embodiments of the present disclosure may reduce an area of a memory and further integrate the memory.

Hereafter, embodiments in accordance with the technical spirit of the present disclosure will be described with reference to the accompanying drawings.

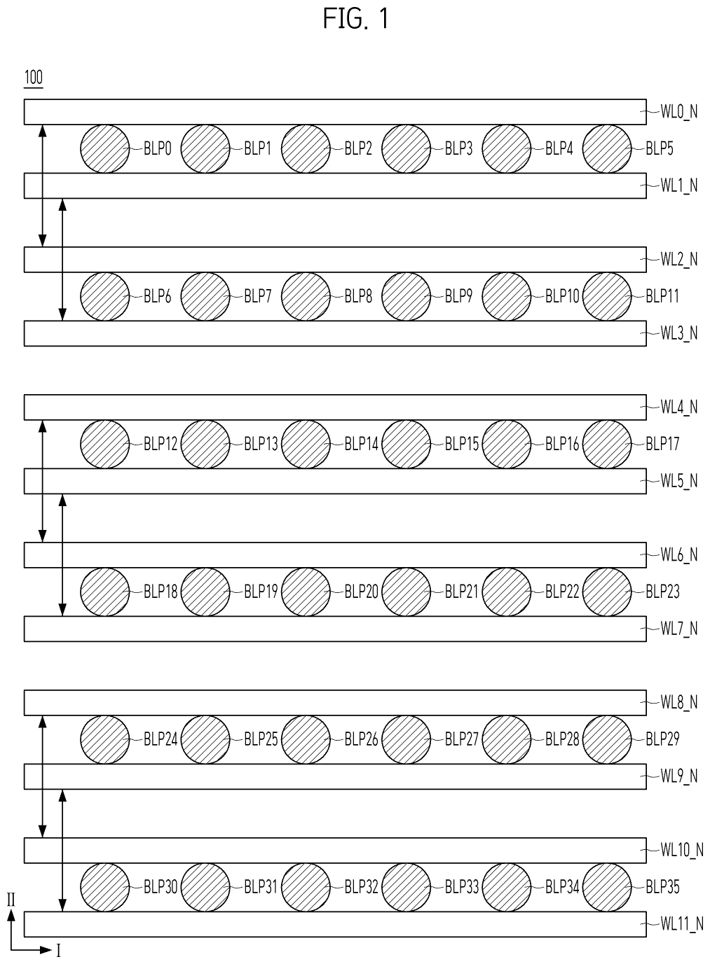

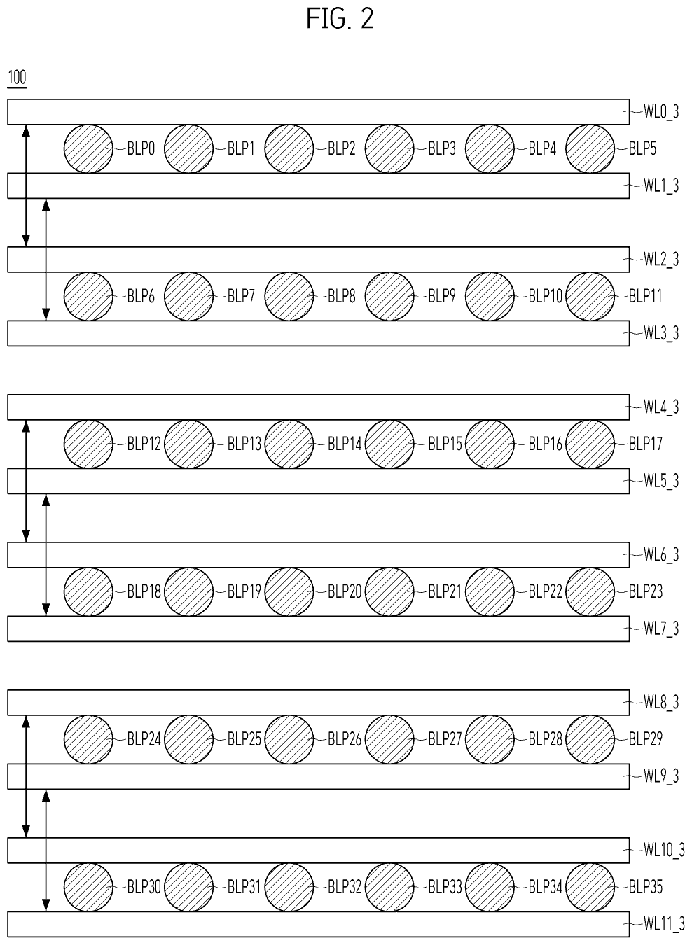

FIGS. 1 and 2 are diagrams illustrating the structure of word lines in a cell array 100 of a memory in accordance with an embodiment of the present disclosure. The cell array 100 may be formed of N layers, where N is an integer of 2 or more, and may include M word lines WL arranged in each layer, where M is an integer of 2 or more and is 12 herein, FIG. 1 may be a plan view illustrating an N^{th} layer, and FIG. 2 may be a plan view illustrating a third layer. In FIGS. 1 and 2, a first direction ‘I’ may be perpendicular to a second direction ‘II’.

Referring to FIG. 1, the cell array 100 may include word lines WL0_N to WL11_N and bit line pillars BLP0 to BLP35. The bit line pillars BLP0 to BLP35 may refer to pillar-shaped bit lines. The bit line pillars BLP0 to BLP35 may be disposed to pass and intersect between two word lines in each of the word line layers. For example, the bit line pillars BLP0 to BLP5 may pass between the word lines WL0_3 and WL1_3 in the third layer (FIG. 2) and between the word lines WL0_N and WL1_N in the N^{th} layer (FIG. 1).

Memory cells (not illustrated) may be disposed at intersections between the word lines WL and the bit line pillars BLP, respectively. Because the bit line pillars BLP intersect with two word lines WL for each word line layer, the cell array 100 may include [number of bit line pillars]×[number of word line layers]×two memory cells. For example, a memory cell may be disposed at an intersection between the bit line pillar BLP0 and the word line WL0_1 of the first layer, and a memory cell may be disposed at an intersection between the bit line pillar BLP0 and the word line WL1_1 of the first layer. Likewise, memory cells may be disposed at intersections between the bit line pillar BLP0 and the word lines WL0_2 to WL0_N and WL1_2 to WL1_N of the second to N^{th} layers, respectively.

Two or more word lines of each layer may be grouped and driven together. In FIGS. 1 and 2, two word lines connected by arrows may be shorted to each other and driven together. That is, the word lines WL0 and WL2 may be shorted to each other and driven together, the word lines WL1 and WL3 may be shorted to each other and driven together, the word lines WL4 and WL6 may be shorted to each other and driven together, the word lines WL5 and WL7 may be shorted to each other and driven together, the word lines WL8 and WL10 may be shorted to each other and driven together, and the word lines WL9 and WL11 may be shorted to each other and driven together. This may be the same for not only the word lines WL0_N to WL11_N of the N^{th} layer illustrated in FIG. 1 and the word lines WL0_3 to WL11_3 of the third layer illustrated in FIG. 2, but also the word lines of all layers.

FIG. 1 illustrates the word lines WL0_N to WL11_N of the N^{th} layer, and FIG. 2 illustrates the word lines WL0_3 to WL11_3 of the third layer. The word lines of the remaining layers may also have the same structure as the structure in FIGS. 1 and 2.

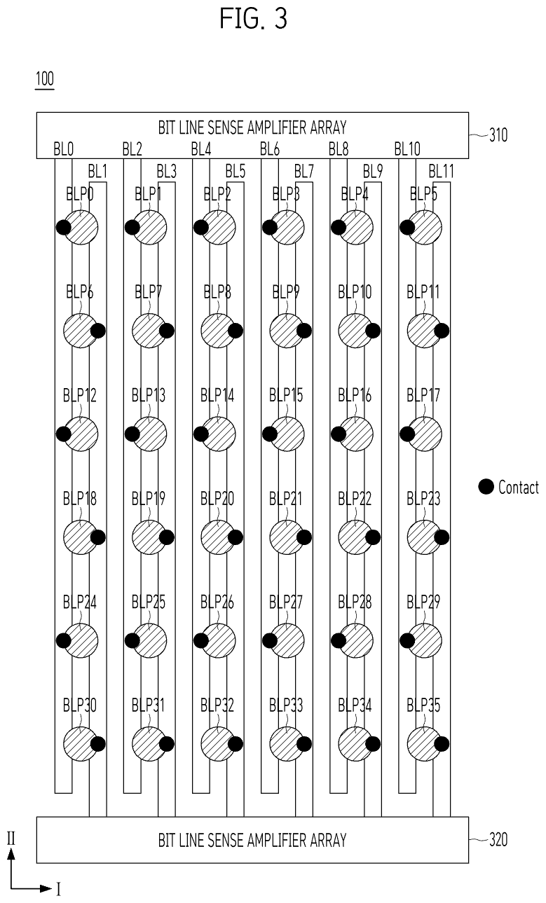

FIG. 3 is a diagram illustrating bit lines BL0 to BL11 for electrical connection among the bit line pillars BLP0 to BLP35 of FIGS. 1 and 2. FIG. 3 also illustrates bit line sense amplifier arrays 310 and 320 around the cell array 100.

The bit lines BL0 to BL11 may be disposed below the word lines WL0_1 to WL11_1 of the first layer. The bit lines BL0 to BL11 may be lines for connecting the bit line pillars BLP0 to BLP35 and the bit line sense amplifier arrays 310 and 320.

Referring to contacts of FIG. 3, bit line pillars BLP0, BLP12, and BLP24 may be connected to the bit line BL0. Accordingly, the bit line pillars BLP0, BLP12, and BLP24 may be electrically identical bit lines. Bit line pillars BLP6, BLP18, and BLP30 may be connected to the bit line BL1. Accordingly, the bit line pillars BLP6, BLP18, and BLP30 may be electrically identical bit lines. Likewise, because the bit line pillars BLP1, BLP13, and BLP25 are connected to the bit line BL2, the bit line pillars BLP1, BLP13, and BLP25 may be identical bit lines, and because the bit line pillars BLP7, BLP19, and BLP31 are connected to the bit line BL3, the bit line pillars BLP7, BLP19, and BLP31 may be identical bit lines.

That is, in FIG. 3, bit line pillars BLPX, BLPX+12, and BLPX+24, where X is an integer between 0 and 11, may be identical bit lines electrically connected.

Half of the bit lines BL0 to BL11, for example, even-numbered bit lines BL0, BL2, BL4, BL6, BL8, and BL10 may be connected to the bit line sense amplifier array 310, and the other half, for example, odd-numbered bit lines BL1, BL3, BL5, BL7, BL9, and BL11 may be connected to the bit line sense amplifier array 320. The bit line sense amplifier arrays 310 and 320 may sense and amplify data transmitted to connected bit lines. Each of the bit line sense amplifier arrays 310 and 320 may include a plurality of bit line sense amplifiers.

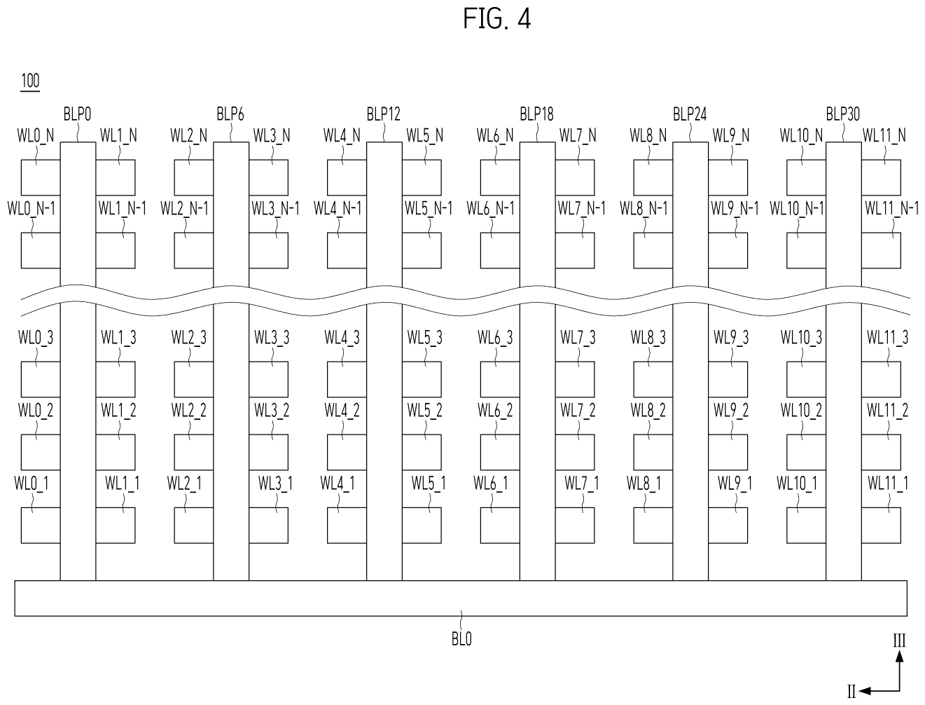

FIG. 4 is a side view of the cell array 100 illustrated in FIGS. 1 to 3. In FIG. 4, a third direction ‘III’ may be a direction orthogonal to a plane defined by the first direction ‘I’ and the second direction ‘II’ in FIGS. 1 to 3.

Referring to FIG. 4, it may be seen that each of the bit line pillars BLP0, BLP6, BLP12, BLP18, BLP24, and BLP30 intersects with two word lines in each layer from the first layer to the N^{th} layer. For example, it may be seen that the bit line pillar BLP0 intersects with the word lines WL0_1 to WL0_N and WL1_1 to WL1_N in the first layer to the N^{th} layer. That is, each of the bit line pillars BLP0, BLP6, BLP12, BLP18, BLP24, and BLP30 may intersect with 2×N word lines.

Below the word lines WL0_1 to WL11_1 of the first layer, the bit line BL0 may be provided to electrically connect some (BLP0, BLP12, and BLP24, see FIG. 3) of the bit line pillars BLP0, BLP6, BLP12, BLP18, BLP24, and BLP30.

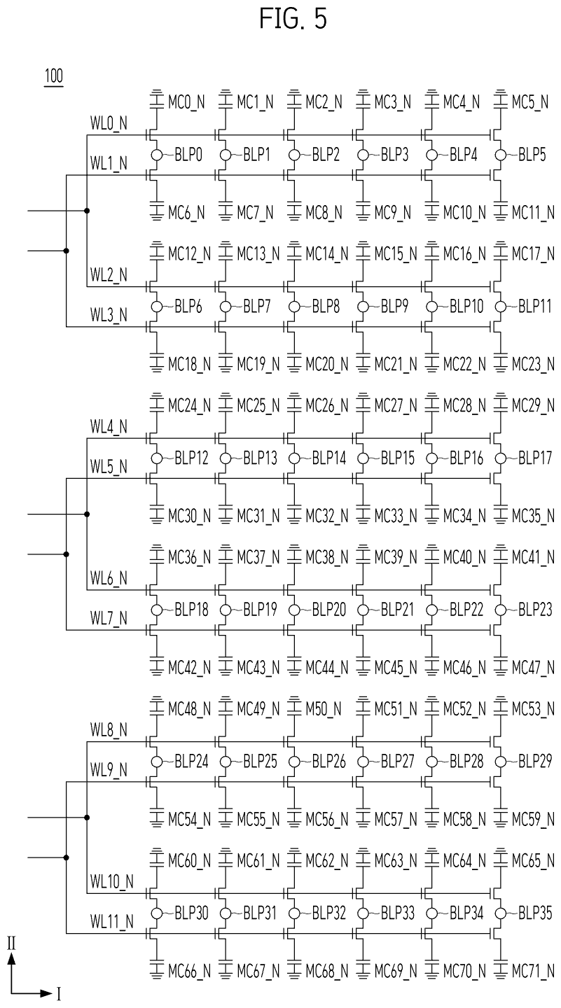

FIG. 5 is a circuit diagram illustrating electrical connection among the word lines WL0_N to WL11_N, the bit line pillars BLP0 to BLP35, and memory cells MC0_N to MC71_N of the N^{th} layer in the cell array 100 illustrated in FIGS. 1 to 4.

The memory cells MC0_N to MC71_N may be disposed at intersections between the bit line pillars BLP0 to BLP35 and the word lines WL0_N to WL11_N, respectively. Because each of the bit line pillars BLP0 to BLP35 intersects with two bit lines, the number of memory cells MC0_N to MC71_N in the N^{th} layer may be twice the number of bit line pillars BLP0 to BLP35. Each of the memory cells MC0_N to MC71_N may include a capacitor for storing data and a transistor for transmitting data stored in the capacitor to a bit line pillar under the control of the word line.

The following describes an operation when the word lines WL0_N and WL2_N shorted to each other are simultaneously activated. As the word line WL0 is activated, the transistors of the memory cells MC0_N to MC5_N may be turned on, so that data stored in the capacitors of the memory cells MC0_N to MC5_N may be transmitted to the bit line pillars BLP0 to BLP5. As the word line WL2 is activated, the transistors of the memory cells MC12_N to MC17_N are turned on, so that data stored in the capacitors of the memory cells MC12_N to MC17_N may be transmitted to the bit line pillars BLP6 to BLP11. The data of the bit line pillars BLP0 to BLP5 may be transmitted to the bit line sense amplifier array 310 through the bit lines BL0, BL2, BL4, BL6, BL8, and BL10 and sensed and amplified, and the data of the bit line pillars BLP6 to BLP11 may be transmitted to the bit line sense amplifier array 320 through the bit lines BL1, BL3, BL5, BL7, BL9, and BL11 and sensed and amplified. That is, even though the two word lines WL0_N and WL2_N are simultaneously activated, the data of the memory cells MC0_N to MC5_N and MC12_N to MC17_N may be transmitted to the bit lines BL0 to BL11 different from one another and sensed and amplified.

Likewise, when the word lines WL1_N and WL3_N are simultaneously activated, data of the memory cells MC6_N to MC11_N corresponding to the word line WL1_N may be transmitted to the bit line sense amplifier array 310 through the bit line pillars BLP0 to BLP5 and the bit lines BL0, BL2, BL4, BL6, BL8, and BL10 and sensed and amplified. Data of the memory cells MC18_N to MC23_N corresponding to the word line WL3_N may be transmitted to the bit line sense amplifier array 320 through the bit line pillars BLP6 to BLP11 and the bit lines BL1, BL3, BL5, BL7, BL9, and BL11 and sensed and amplified.

In the cell array 100 illustrated in FIGS. 1 to 5, because the word lines WL are shorted by the two, the word lines WL may form a pair by the two and be simultaneously driven. With such a structure, the number of word lines WL that need to be driven may be reduced by half, which may mean that an area of a word line driving circuit (not illustrated) may be reduced by half. Because the word line driving circuit is a circuit that occupies a large area in the memory, when the area of the word line driving circuit is reduced by half, the area of the memory may be reduced and a more highly integrated memory may be manufactured.

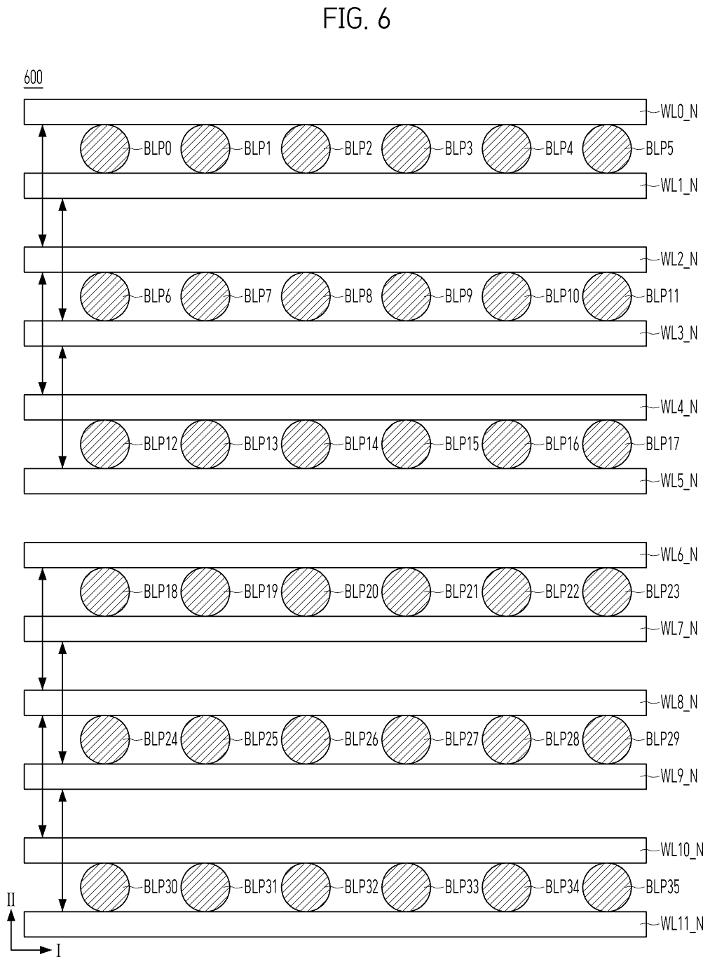

FIG. 6 is a diagram illustrating the structure of word lines in a cell array 600 of a memory in accordance with another embodiment of the present invention. The cell array 600 may be formed of N layers and include M word lines WL arranged in each layer. FIG. 6 may be a plan view illustrating an N^{th} layer. In FIG. 6, the first direction ‘I’ may be perpendicular to the second direction ‘II’.

Referring to FIG. 6, the cell array 600 may include word lines WL0_N to WL11_N and bit line pillars BLP0 to BLP35, similar to FIG. 1. The bit line pillars BLP0 to BLP35 may refer to pillar-shaped bit lines. The bit line pillars BLP0 to BLP35 may be disposed to pass and intersect between two word lines in each of the word line layers. For example, the bit line pillars BLP0 to BLP5 may pass between the word lines WL0_N and WL1_N in the N^{th} layer (FIG. 1).

The word lines of each layer may form a group by three and be simultaneously driven. In FIG. 6, word lines connected by arrows may be shorted to one another and driven together. The word lines WL0_N, WL2_N, and WL4_N may be shorted to one another and driven together, the word lines WL1_N, WL3_N, and WL5_N may be shorted to one another and driven together, the word lines WL6_N, WL8_N, and WL10_N may be shorted to one another and driven together, and the word lines WL7_N, WL9_N, and WL11_N may be shorted to one another and driven together.

FIG. 6 illustrates the word lines WL0_N to WL11_N of the N^{th} layer, and the word lines of the remaining layers may also have the same structure as the structure in FIG. 6.

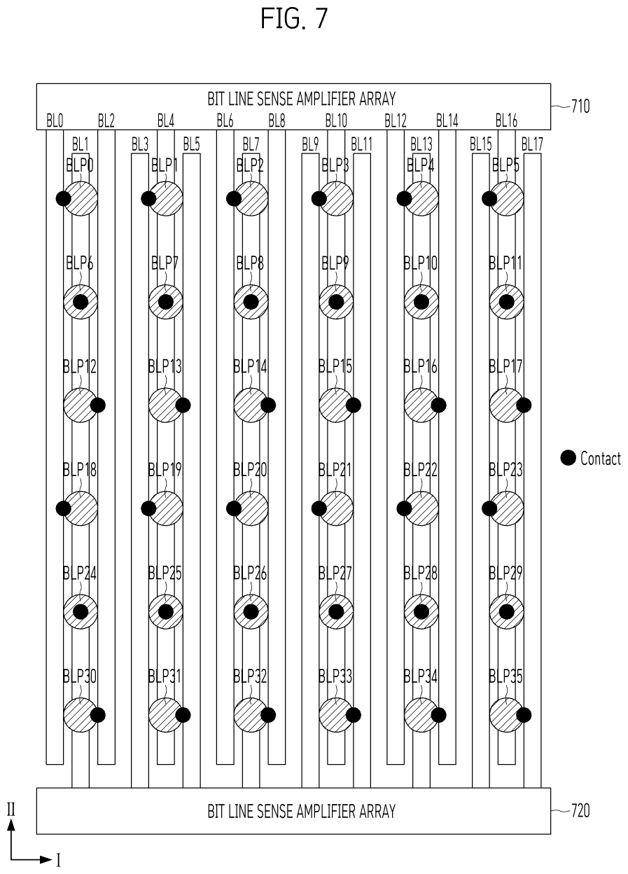

FIG. 7 is a diagram illustrating bit lines BL0 to BL17 for electrical connection among the bit line pillars BLP0 to BLP35 of FIG. 6. FIG. 7 also illustrates bit line sense amplifier arrays 710 and 720 around the cell array 600.

The bit lines BL0 to BL17 may be disposed below the word lines WL0_1 to WL11_1 of the first layer. The bit lines BL0 to BL17 may be lines for connecting the bit line pillars BLP0 to BLP35 and the bit line sense amplifier arrays 710 and 720.

Referring to contacts of FIG. 7, bit line pillars BLP0 and BLP18 may be connected to the bit line BL0. Accordingly, the bit line pillars BLP0 and BLP18 may be electrically identical bit lines. Bit line pillars BLP6 and BLP24 may be connected to the bit line BL1. Accordingly, the bit line pillars BLP6 and BLP24 may be electrically identical bit lines. Likewise, because the bit line pillars BLP12 and BLP30 are connected to the bit line BL2, the bit line pillars BLP12 and BLP30 may be identical bit lines.

That is, in FIG. 7, bit line pillars BLPK and BLPK+18, where K is an integer between 0 and 17, may be identical bit lines electrically connected.

Half of the bit lines BL0 to BL17, for example, even-numbered bit lines BL0, BL2, BL4, BL6, BL8, BL10, BL12, BL14, and BL16 may be connected to the bit line sense amplifier array 710, and the other half, for example, odd-numbered bit lines BL1, BL3, BL5, BL7, BL9, BL11, BL13, BL15, and BL17 may be connected to the bit line sense amplifier array 720. The bit line sense amplifier arrays 710 and 720 may sense and amplify data transmitted to connected bit lines. Each of the bit line sense amplifier arrays 710 and 720 may include a plurality of bit line sense amplifiers.

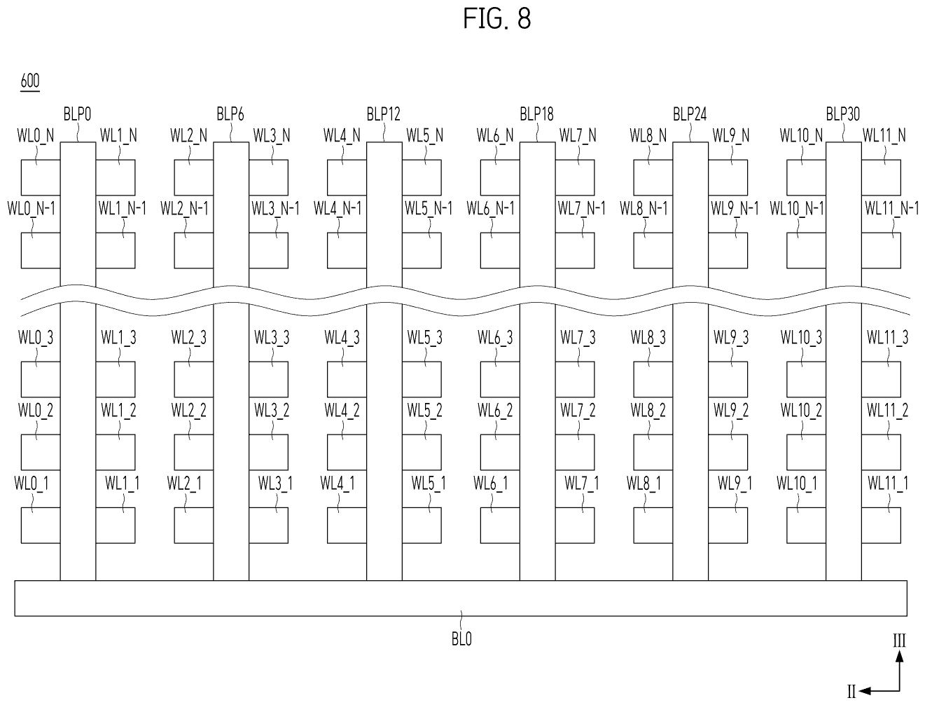

FIG. 8 is a side view of the cell array 600 illustrated in FIGS. 6 and 7. In FIG. 8, a third direction ‘III’ may be a direction orthogonal to a plane defined by the first direction ‘I’ and the second direction ‘II’ in FIGS. 6 and 8.

Referring to FIG. 8, it may be seen that each of the bit line pillars BLP0, BLP6, BLP12, BLP18, BLP24, and BLP30 intersects with two word lines in each layer from the first layer to the N^{th} layer. For example, it may be seen that the bit line pillar BLP0 intersects with the word lines WL0_1 to WL0_N and WL1_1 to WL1_N in the first layer to the N^{th} layer. That is, each of the bit line pillars BLP0, BLP6, BLP12, BLP18, BLP24, and BLP30 may intersect with 2×N word lines.

Below the word lines WL0_1 to WL11_1 of the first layer, the bit line BL0 may be provided to electrically connect some (BLP0 and BLP18, see FIG. 7) of the bit line pillars BLP0, BLP6, BLP12, BLP18, BLP24, and BLP30.

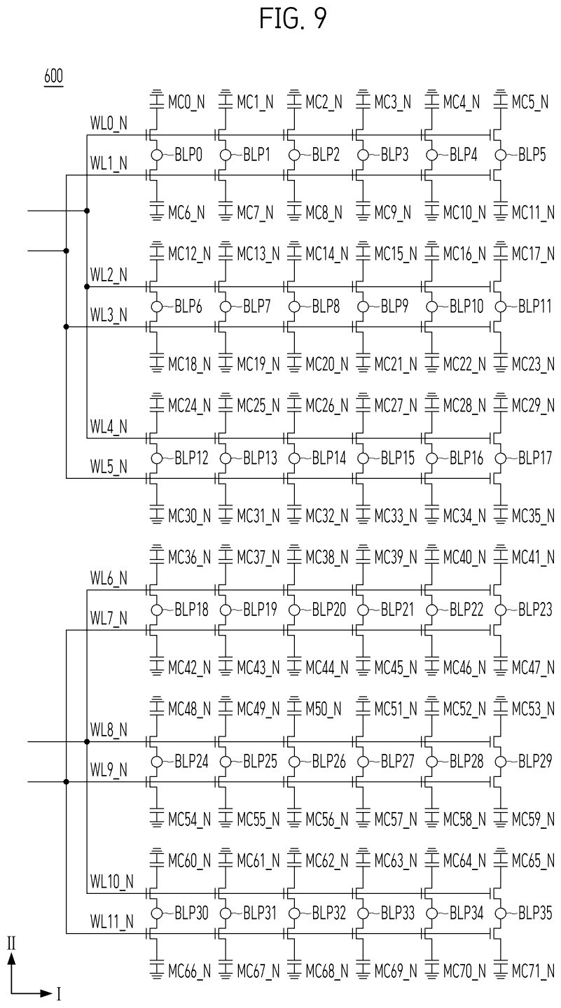

FIG. 9 is a circuit diagram illustrating electrical connection among the word lines WL0_N to WL11_N, the bit line pillars BLP0 to BLP35, and memory cells MC0_N to MC71_N of the N^{th} layer in the cell array 600 illustrated in FIGS. 6 to 8.

The memory cells MC0_N to MC71_N may be disposed at intersections between the bit line pillars BLP0 to BLP35 and the word lines WL0_N to WL11_N, respectively. Because each of the bit line pillars BLP0 to BLP35 intersects with two bit lines, the number of memory cells MC0_N to MC71_N in the N^{th} layer may be twice the number of bit line pillars BLP0 to BLP35. Each of the memory cells MC0_N to MC71_N may include a capacitor for storing data and a transistor for transmitting data stored in the capacitor to the bit line pillar under the control of the word line.

The following describes an operation when the word lines WL0_N, WL2_N, and WL4_N shorted to one another are simultaneously activated. As the word line WL0_N is activated, the transistors of the memory cells MC0_N to MC5_N may be turned on, so that data stored in the capacitors of the memory cells MC0_N to MC5_N may be transmitted to the bit line pillars BLP0 to BLP5. As the word line WL2_N is activated, the transistors of the memory cells MC12_N to MC17_N are turned on, so that data stored in the capacitors of the memory cells MC12_N to MC17_N may be transmitted to the bit line pillars BLP6 to BLP11. As the word line WL4_N is activated, the transistors of the memory cells MC24_N to MC29_N are turned on, so that data stored in the capacitors of the memory cells MC24_N to MC29_N may be transmitted to the bit line pillars BLP12 to BLP17. The data of the bit line pillars BLP0 to BLP5 may be transmitted to the bit lines BL0, BL3, BL6, BL9, BL12, and BL15, the data of the bit line pillars BLP6 to BLP11 may be transmitted to the bit lines BL1, BL4, BL7, BL10, BL13, and BL16, and the data of the bit line pillars BLP12 to BLP17 may be transmitted to the bit lines BL2, BL5, BL8, BL11, BL14, and BL17. The data of the bit lines BL0 to BL17 may be sensed and amplified by the bit line sense amplifier arrays 710 and 720.

Even when the word lines WL1_N, WL3_N, and WL5_N are simultaneously activated, even when the word lines WL6_N, WL8_N, and WL10_N are simultaneously activated, and even when the word lines WL7_N, WL9_N, and WL11_N are simultaneously activated, data of 18 memory cells may be transmitted to the bit line sense amplifier arrays 710 and 720 through 18 bit line pillars and 18 bit lines and be sensed and amplified as described above.

In the cell array 600 illustrated in FIGS. 6 to 9, because the word lines WL are shorted by the three, the word lines WL may form a group by three and be simultaneously driven. With such a structure, the number of word lines WL that need to be driven may be reduced by ⅓, which may mean that an area of a word line driving circuit may be greatly reduced.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A memory comprising:
a plurality of word lines formed of N layers, M word lines being arranged in each layer, among the plurality of word lines, where each of N and M is an integer of 2 or more;
a plurality of bit line pillars; and
a plurality of memory cells disposed at intersections between the plurality of word lines and the plurality of bit line pillars, respectively,
wherein two or more word lines of the plurality of word lines are grouped and driven together.

2. The memory of claim 1, wherein, among the plurality of word lines, the grouped word lines word lines are included in a same layer.

3. The memory of claim 2, wherein the plurality of bit line pillars are mutually electrically connected while forming a group in units of L, where L is an integer of 2 or more.

4. The memory of claim 3, wherein, among the bit line pillars, bit line pillars intersecting the grouped word lines are not mutually electrically connected.

5. The memory of claim 1, wherein each of the plurality of memory cells includes a transistor and a capacitor.

6. The memory of claim 1, wherein a first-half of the plurality of bit line pillars are connected to first bit line sense amplifiers disposed on a first side in a direction perpendicular to the plurality of bit line pillars, and a second-half of the plurality of bit line pillars are connected to second bit line sense amplifiers disposed on a second side in the direction perpendicular to the plurality of bit line pillars.

7. The memory of claim 1, wherein the grouped word lines among the plurality of word lines are shorted to each other.

8. The memory of claim 1, wherein each of the plurality of bit line pillars is disposed to pass between two word lines in each of the N layers.

9. A memory comprising:
a plurality of word lines;
a plurality of bit lines; and
a plurality of memory cells connected to one of the plurality of word lines and one of the plurality of bit lines,
wherein two or more word lines of the plurality of word lines are grouped and driven together.

10. The memory of claim 9, wherein the grouped word lines include a first word line and a second word line, and
among the plurality of bit lines, first bit lines connected to memory cells connected to the first word line and second bit lines connected to memory cells connected to the second word line do not overlap each other.

11. The memory of claim 9, wherein each of the plurality of memory cells includes a transistor and a capacitor.
